(19) United States
(12) Patent Application Publication
(10) Pub. No.: US 2012/0025238 A1
(43) Pub. Date: Feb. 2, 2012

(54) LED PACKAGE

(75) Inventor: SHEN-BO LIN, Hukou (TW)

(73) Assignee: ADVANCED OPTOELECTRONIC TECHNOLOGY, INC., Hsinchu Hsien (TW)

(21) Appl. No.: 12/965,901

(22) Filed: Dec. 12, 2010

(30) Foreign Application Priority Data
Jul. 29, 2010 (CN) 201010240174.7

(51) Int. Cl. H01L 33/56

(52) U.S. Cl. 257/98; 257/E33.068

(57) ABSTRACT

An LED package comprises a substrate, an LED die, and an encapsulating layer. The substrate has circuit formed thereon. The LED die is arranged on the substrate and electrically connected to the circuit of the substrate. The encapsulating layer covers the LED die and at least a part of the substrate. The encapsulating layer and the substrate are made of cycloaliphatic epoxide.

### BACKGROUND

1. Technical Field

The present disclosure generally relates to LED technology, and particularly to an LED package.

2. Description of the Related Art

Light emitting diodes' (LEDs') many advantages, such as high luminosity, low operational voltage, low power consumption, compatibility with integrated circuits, easy driving, long-term reliability, and environmental friendliness, have promoted the LEDs as a widely used light source. Light emitting diodes are commonly applied in lighting applications.

LED packages must, however, overcome certain manufacturing challenges. Light transmissive resins for encapsulating semiconductor devices have heavily relied on blends of bisphenol-A epoxy and aliphatic anhydride curing agents. The materials used heretofore become discolored in extended storage at temperatures above 80° C., through yellow to brown, whereby their light transmittancy decreases considerably. Furthermore, because of the aromatic character of bisphenol-A based epoxy resins, these encapsulants would be less stable to ultraviolet component. Such degradation can lead to discoloration of the encapsulant, and accordingly reduce light transmittance and product lifetime. Other encapsulating material, such as silicone, also has problem of short product lifetime.

What is needed, therefore, is an LED package which can increase product lifetime, and ameliorate the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the LED package. Moreover, in the drawings, like reference numerals designate corresponding parts throughout the views.

FIG. 1 is a schematic view of an LED package in accordance with a first embodiment.

FIG. 2 is a schematic view of a different structure of an LED package in accordance with a first embodiment.

FIG. 3 is a schematic view of another structure of an LED package in accordance with a first embodiment.

FIG. 4 is a schematic view of an LED package in accordance with a second embodiment.

FIG. 5 is a schematic view of a different structure of an LED package in accordance with a second embodiment.

### DETAILED DESCRIPTION

Embodiments of an LED package as disclosed are described in detail here with reference to the drawings.

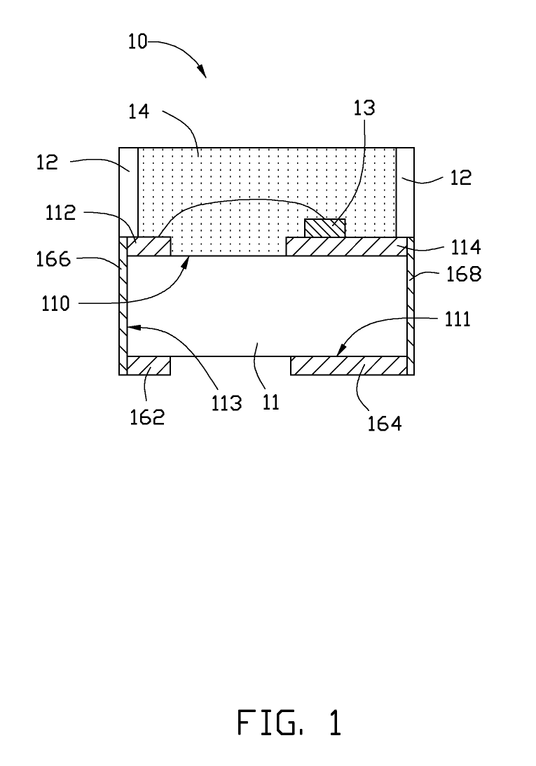

Referring to FIG. 1, an LED package 10 in accordance with a first embodiment includes a substrate 11, a reflective cup 12, an LED die 13, and an encapsulating layer 14. The substrate 11 is configured for supporting the LED die 13. A circuit is arranged on the substrate 11 to provide electricity to the LED die 13.

In this embodiment, the substrate 11 and the reflective cup 12 are formed integrally. In another embodiment, the reflective cup 12 is separately formed from the substrate 11 and arranged on the substrate 11 for receiving the LED die 13 and improving light emitting efficiency of the LED die 13.

In this embodiment, the circuit of the substrate 11 includes a first electrode 112 and a second electrode 114 arranged on a first surface 110 of the substrate 11. Two contacting electrodes 162 and 164 are arranged on another second surface 111 opposite to the first surface 110 of the substrate 11. The first electrode 112 electrically connects with the first contacting electrode 162 through a first connecting electrode 166. The second electrode 114 electrically connects with the second contacting electrode 164 through a second connecting electrode 168. The first connecting electrode 166 and the second connecting electrode 168 are arranged on the side surface 113 between the first surface 110 and the second surface 112.

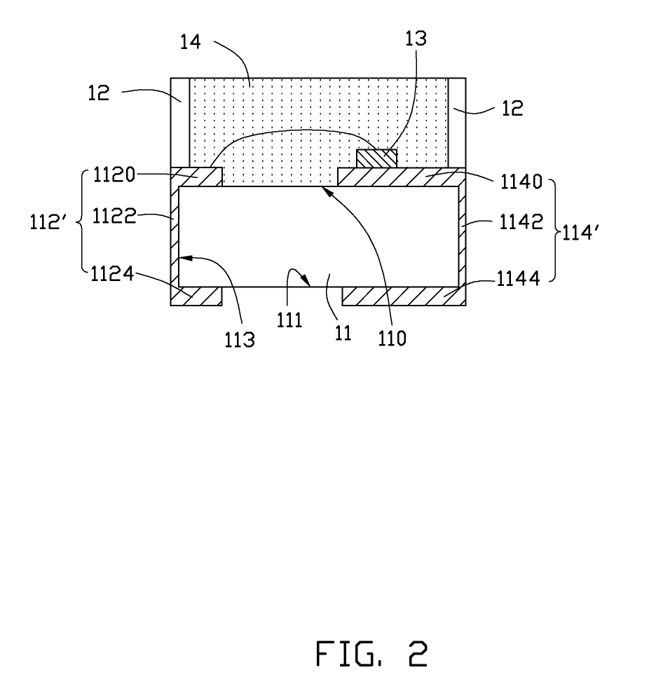

Referring to FIG. 2, the first electrode 112, the first connecting electrode 166, and the first contacting electrode 162 of FIG. 1 are formed integrally as a monolithic first electrode 112′ in this alternative structure. The first end portion 1120 of the first electrode 112′ is arranged between the substrate 11 and the reflective cup 12 and exposed on the surface 110 of the substrate 11 on the bottom of the reflective cup 12 for electrically connecting with the LED die 13. The main body 1122 of the first electrode 112′ extends on the side surface 113 outside the substrate 11. The second end portion 1124 of the first electrode 112′ angles inwardly on the second surface 111 of the substrate 11 for electrically connecting with an outside circuit.

The second electrode 114, the second connecting electrode 168, and the second contacting electrode 164 of FIG. 1 are formed integrally as a monolithic second electrode 114′ in this alternative structure. The first end portion 1140 of the second electrode 114′ is arranged between the substrate 11 and the reflective cup 12 and exposed on the surface 110 of the substrate 11 on the bottom of the reflective cup 12 for electrically connecting with the LED die 13. The main body 1142 of the second electrode 114′ extends on the side surface 113 outside the substrate 11. The second end portion 1144 of the second electrode 114′ angles inwardly on the second surface 111 of the substrate 11 for electrically connecting with an outside circuit.

The LED die 13 is arranged on the substrate 11 inside the reflective cup 12. The positive and negative electrodes of the LED die 13 electrically connect with the first and second electrodes 112′, 114′ on the bottom of the reflective cup 12. In this embodiment, the LED die 13 is arranged on the second electrode 114′, one electrode of the LED die 13 electrically connects with the second electrode 114′, and another electrode electrically connects with the first electrode 112′ through wire.

The encapsulating layer 14 is arranged inside the reflective cup 12 and covering the LED die 13 and a part of the first surface 110 of the substrate 11. The encapsulating layer 14 is composed of cycloaliphatic epoxide and can be made by resin transfer molding, injection molding, spot glue molding, or printing coating. The reflective cup 12 can further be doped with titanium dioxide (TiO₂) for improving light reflection.

Preferably, the encapsulating layer 14 can further be doped with luminescent material, such as garnet compound, silicate compound, sulfide compound, or nitride compound. Moreover, the substrate 11 can be made of cycloaliphatic epoxide and glass fiber, and the reflective cup 12 and the encapsulating layer 14 composed of cycloaliphatic epoxide with resin transfer molding, or embedding molding.

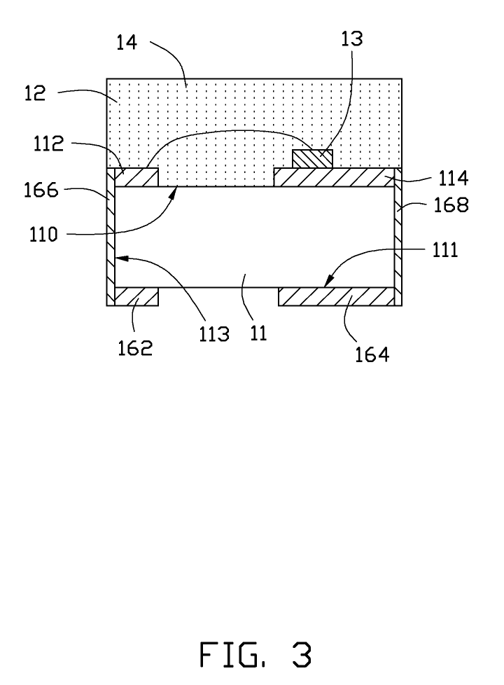

The reflective cup 12 is optional. An LED package can comprise the encapsulating layer 14 covering the LED die 13 and the first surface 110 of the substrate 11 without the reflective cup 12 as shown in FIG. 3.

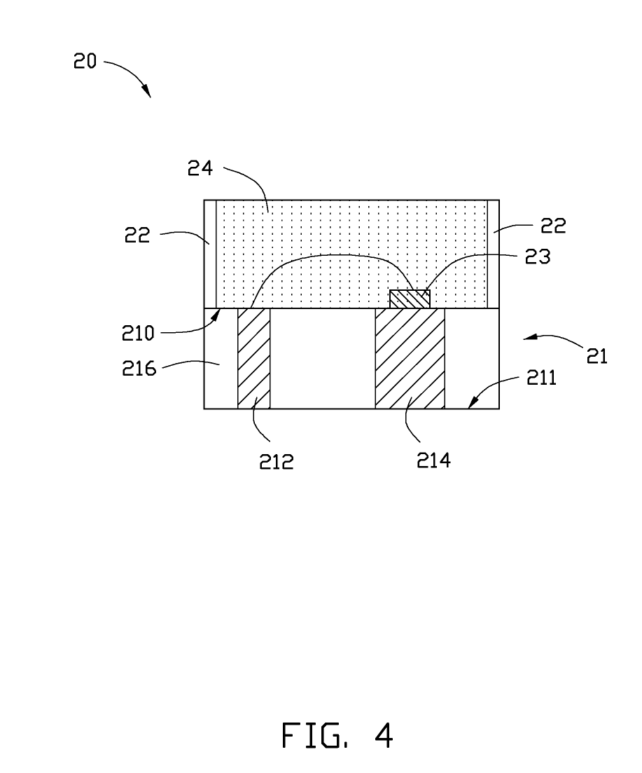

Referring to FIG. 4, an LED package 20 in accordance with a second embodiment includes a substrate 21, a reflective cup 22, an LED die 23, and an encapsulating layer 24. The substrate 21 is configured for supporting the LED die 23. A circuit is arranged on the substrate 21 to provide electricity to the LED die 23. In this embodiment, the substrate 21 and the reflective cup 22 are formed integrally. The reflective cup 22 is arranged on the substrate 21 for receiving the LED die 23 and improving light emitting efficiency of the LED die 23.

The circuit of the substrate 21 includes a first electrode 212 and a second electrode 214 respectively embedded in the substrate 21. The first electrode 212 and the second electrode 214 pass through the first surface 210 and the second surface 211 of the substrate 21. In this embodiment, the end surfaces of the first electrode 212 and the second electrode 214 are coplanar with the first surface 210 and the second surface 211. The first electrode 212 and the second electrode 214 are made of conductive metals and electrically isolated by insulating material 216. One end of the first electrode 212 and the second electrode 214 is exposed through the first surface 210 of the substrate 21 for electrically connecting with the LED die 23. The other end of the first electrode 212 and the second electrode 214 extends outside the substrate 21 on the second surface 211 for electrically connecting with an outside circuit.

The LED die 23 is arranged on the substrate 21 inside the reflective cup 22. The positive and negative electrodes of the LED die 23 are electrically connecting with the first electrode 212 and the second electrode 214 on the bottom of the reflective cup 22. In this embodiment, the LED die 23 is arranged on the second electrode 214, one electrode of the LED die 23 electrically connecting with the second electrode 214, and another electrode electrically connecting with the first electrode 212 through wire.

The encapsulating layer 24 is arranged inside the reflective cup 22 and covers the LED die 23 and a part of the first surface 210 of the substrate 21. The encapsulating layer 24 is composed of cycloaliphatic epoxide and can be made by resin transfer molding, injection molding, spot glue molding, or printing coating. The reflective cup 22 can further be doped with titanium dioxide (TiO₂) for improved light reflection.

Preferably, the encapsulating layer 24 can further be doped with luminescent material, such as garnet compound, silicate compound, sulfide compound, or nitride compound. Moreover, the substrate 21 can be made of cycloaliphatic epoxide and glass fiber, and the reflective cup 22 and the encapsulating layer 24 are composed of cycloaliphatic epoxide with resin transfer molding, or embedding molding. The first electrode 212, the second electrode 214, and the insulating material 216 can be made by heat lamination or embedding molding. The reflective cup 22 can be made by transfer molding or injection molding.

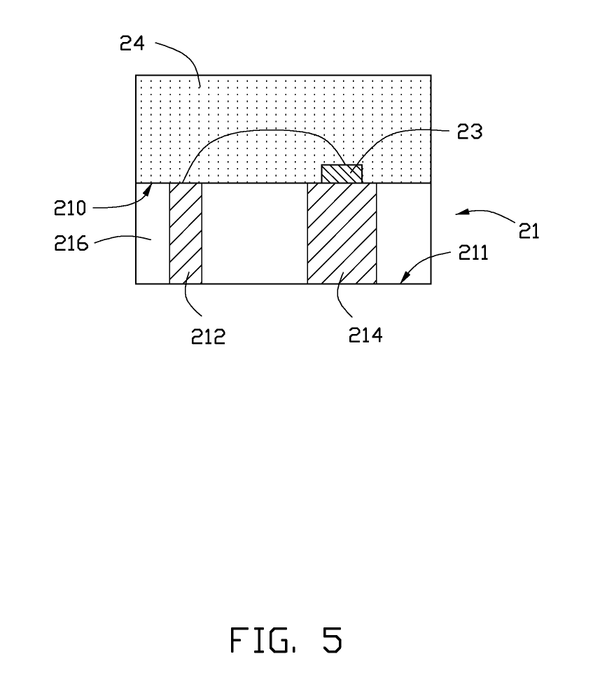

The reflective cup 22 is optional. An LED package can comprise the encapsulating layer 24 covering the LED die 23 and the first surface 210 of the substrate 21 without the reflective cup 22 as shown in FIG. 5.

It is to be understood, however, that even though numerous characteristics and advantages of the disclosure have been set forth in the foregoing description, together with details of the structures and functions of the embodiment(s), the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED package comprising:
a substrate with circuit formed thereon;
an LED die arranged on the substrate and electrically connected to the circuit of the substrate; and
an encapsulating layer covering the LED die and at least a part of the substrate, wherein the substrate and the encapsulating layer are composed of cycloaliphatic epoxide.

2. The LED package of claim 1 further comprising a reflective cup arranged on the substrate surrounding the LED die.

3. The LED package of claim 2, wherein the reflective cup is formed integrally with the substrate.

4. The LED package of claim 2, wherein the reflective cup is composed of cycloaliphatic epoxide.

5. The LED package of claim 1, wherein the cycloaliphatic epoxide is doped with titanium dioxide.

6. The LED package of claim 1, wherein the encapsulating layer includes luminescent material.

7. The LED package of claim 6, wherein the luminescent material is garnet compound, silicate compound, sulfide compound, or nitride compound.

8. The LED package of claim 1, wherein the substrate includes a first surface for supporting the LED die, a second surface opposite to the first surface, and a side surface between the first surface and the second surface, and wherein the circuit includes a first electrode and a second electrode arranged on the first surface connecting respectively with the LED die, two connecting electrodes arranged on the side surface, and two contacting electrodes arranged on the second surface electrically connecting with the first electrode and the second electrode through the two connecting electrodes.

9. The LED package of claim 8, wherein the first electrode, one of the connecting electrodes, and one of the contacting electrodes are formed integrally as a monolithic piece, and the second electrode, the other one of the connecting electrodes, and the other one of the contacting electrodes are formed integrally as a monolithic piece.

10. The LED package of claim 1, wherein the substrate includes a first surface for supporting the LED die, a second surface opposite to the first surface, and a side surface between the first surface and the second surface, and wherein the circuit includes a first electrode and a second electrode passing through the substrate and electrically connecting with the LED die.
